(19) United States
(12) Patent Application Publication
(10) Pub. No.: US 2026/0372048 A1
(43) Pub. Date: Nov. 19, 2026

(54) CIRCUIT CELLS HAVING CONDUCTION PATH BETWEEN FRONTSIDE POWER RAIL AND BACKSIDE POWER RAIL

(71) Applicant: TAIWAN SEMICONDUCTOR MANUFACTURING COMPANY, LTD., Hsinchu (TW)

(72) Inventors: Ching-Yu HUANG, Hsinchu (TW); Chun-Hsuang WANG, Hsinchu (TW); Shih-Wei PENG, Hsinchu (TW); Wei-Cheng LIN, Hsinchu (TW); Jiann-Tyng TZENG, Hsinchu (TW)

(21) Appl. No.: 19/754,415

(22) Filed: Jul. 27, 2026

Related U.S. Application Data
(62) Division of application No. 18/398,437, filed on Dec. 28, 2023.

(51) Int. Cl. H10W 20/20; H10D 30/01; H10D 30/43; H10D 30/62; H10D 30/67; H10D 62/10; H10D 64/01; H10D 84/01; H10D 84/03; H10D 84/85

(52) U.S. Cl. CPC H10W 20/20; H10D 30/014; H10D 30/024; H10D 30/43; H10D 30/6211; H10D 30/6735; H10D 30/6757; H10D 62/121; H10D 64/017; H10D 84/0186; H10D 84/0193; H10D 84/038; H10D 84/853

(57) ABSTRACT

A method of manufacturing an integrated circuit includes forming a first backside via-connector conductively connected to the source region of a first-type transistor, and fabricating a backside signal line in a first backside metal layer at a backside of the substrate. The method also includes fabricating a first backside power rail, in a second backside metal layer, which is directly connected to the first backside via-connector with a first extended via-connector. The first backside metal layer is between the second backside metal layer and the substrate.

### PRIORITY CLAIM AND CROSS-REFERENCE

The present application is a divisional of U.S. application Ser. No. 18/398,437, filed Dec. 28, 2023, which is incorporated herein by reference in its entirety.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout diagram of an integrated circuit having frontside power rails and backside power rails, in accordance with some embodiments.

FIGS. 2A-2D and FIGS. 3A-3D are cross-sectional views of the integrated circuit in FIG. 1 along various cutting planes, in accordance with some embodiments.

FIG. 4 is layout diagram of an integrated circuit having arrays of backside power rails, in accordance with some embodiments.

FIG. 5 is a layout diagram of an integrated circuit selectively labeled with geometric relationships, in accordance with some embodiments.

FIGS. 6A-6B are layout diagrams of a circuit cell connected to frontside power rails and backside power rails, in accordance with some embodiments.

FIGS. 7A-7C are layout diagrams of power pickup cells, in accordance with some embodiments.

FIG. 7D is a cross-sectional view of the power pickup cells in FIGS. 7A-7C along the cutting plane AA′, in accordance with some embodiments.

FIGS. 8A-8B are layout diagrams of a single-stage cell in the form of a DSP cell, in accordance with some embodiments.

FIG. 8C is an alternative backside layout diagram of the single-stage cell having the frontside layout diagram of FIG. 8A, in accordance with some embodiments.

FIG. 9 is a layout diagram of an integrated circuit having single-stage cells and multi-stage cells, in accordance with some embodiments.

FIG. 10A is another example implementation of the power pickup cell, in accordance with some embodiments.

FIG. 10B is a cross-sectional view of the power pickup cell in FIG. 10A along the cutting plane AA′, in accordance with some embodiments.

FIG. 11 is a flowchart of a method of generating an integrated circuit having backside power rails, in accordance with some embodiments.

FIG. 12 is a flowchart of a method of manufacturing an integrated circuit, in accordance with some embodiments.

FIG. 13 is a block diagram of an electronic design automation (EDA) system in accordance with some embodiments.

FIG. 14 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an integrated circuit includes frontside power rails and backside power rails extending in a first direction. Some of the circuit cells in the integrated circuit include backside signal lines which are formed in a first backside metal layer (e.g., BM0) at the backside of the substrate. The frontside power rails are formed in a frontside metal layer (e.g., M0) at the frontside of a substrate, while the backside power rails are formed in a second backside metal layer (e.g., BM1). The first backside metal layer (e.g., BM0) is between the second backside metal layer (e.g., BM1) and the substrate. Each of a first frontside power rail and a first backside power rail is configured to be maintained at a first supply voltage (e.g., VDD), and each of a second frontside power rail and a second backside power rail is configured to be maintained at a second supply voltage (e.g., VSS).

The integrated circuit also includes a first backside via-connector, a second backside via-connector, a first extended via-connector, and a second extended via-connector. Each of the backside via-connectors passes through the substrate. Each of the extended via-connectors passes through both the first backside metal layer (e.g., BM0) and the interlayer dielectric between the first backside metal layer (e.g., BM0) and the second backside metal layer (e.g., BM1). The source terminal of a PMOS transistor is conductively connected to both the first frontside power rail and the first backside via-connector, and the first extended via-connector is directly connected between the first backside via-connector and the first backside power rail, thereby forming a conduction path between the first frontside power rail and the first backside power rail. The source terminal of an NMOS transistor is conductively connected to both the second frontside power rail and the second backside via-connector, and the second extended via-connector is directly connected between the second backside via-connector and the second backside power rail, thereby forming a conduction path between the second frontside power rail and the second backside power rail. Increasing the number of conduction paths between the frontside power rails and the backside power rails reduces IR drops, thereby improving the power and speed performance of the integrated circuit.

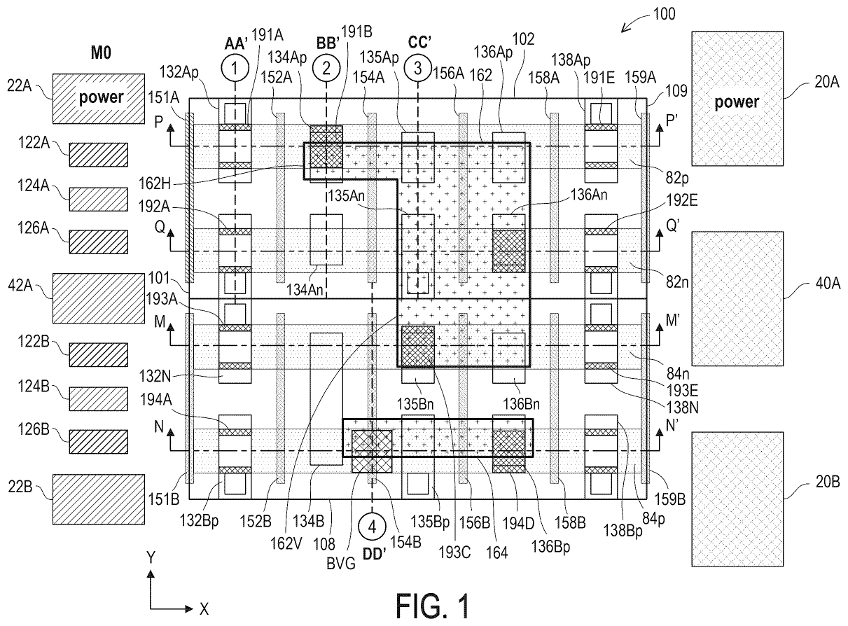

FIG. 1 is a layout diagram of an integrated circuit having frontside power rails and backside power rails, in accordance with some embodiments. The layout diagram of FIG. 1 includes the layout patterns for specifying p-type active-region structures (82p and 84p) and n-type active-region structures (82n and 84n) all extending in the X-direction, gate-conductors (151A-159A and 151B-159B) all extending in the Y-direction, terminal-conductors (132Ap-132Bp, 132N, 138Ap-138Bp, 138N,134Ap-136Ap, 134An-136An, 134B, 135Bn-136Bn, and 135Bp-136Bp) all extending in the Y-direction, and various via-connectors. In the X-Y coordinate system, the X-direction and the Y-direction are perpendicular to each other. In FIG. 1, two adjacent gate-conductors (such as the gate-conductors 152A and 154A) are separated by a pitch distance that is equal to a contacted poly pitch (CPP).

The integrated circuit in FIG. 1 includes a circuit cell 100 bounded by two vertical cell boundaries 101 and 109 extending in the Y-direction and bounded by two horizontal cell boundaries 102 and 108 extending in the X-direction. The dummy gate-conductors 151A and 151B are located at the vertical cell boundary 101, and the dummy gate-conductors 159A and 159B are located at the vertical cell boundary 109.

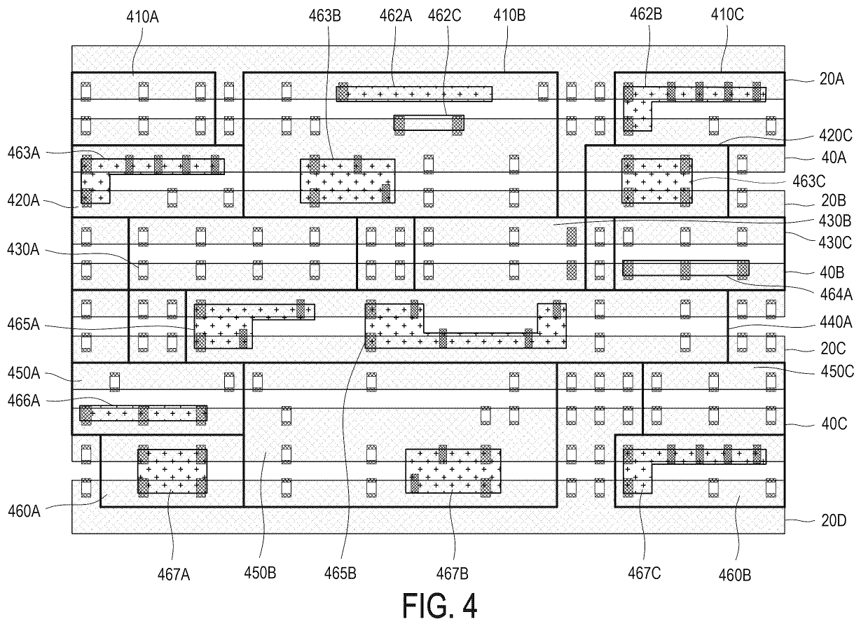

The layout diagram of FIG. 1 also includes the layout conceptual patterns for specifying the backside power rails (20A, 40A, and 20B) extending in the X-direction, the frontside power rails (22A, 42A, and 22B) extending in the X-direction, and frontside signal lines (122A-126A and 122B-126B) extending in the X-direction. In FIG. 1, the full length of each backside power rail (20A, 40A, or 20B) is not directly depicted by the layout conceptual patterns, even though the vertical location of the individual backside power rail and the width of the individual backside power rail along the Y-direction are faithfully specified by the layout conceptual patterns. In fact, each of the backside power rails (20A, 40A, and 20B) has a length that is longer than the width of the circuit cell 100 bounded by two vertical cell boundaries 101 and 109, and each of the backside power rails (20A, 40A, and 20B) extends across both the vertical cell boundaries 101 and 109. In the example layout diagram of FIG. 4, each of the backside power rails (20A, 40A, and 20B) extends along the X-direction and passes multiple circuit cells. Specifically, the backside power rail 20A extends across the circuit cells 410A, 410B, and 410C. The backside power rail 40A extends across the circuit cells 410A, 420A, 410B, 410C, and 420C. The backside power rail 20B extends across the circuit cells 420A, 410B, 430A, 430B, 420C, and 430C.

Similarly, in FIG. 1, the full length of each of the frontside power rails (22A, 42A, or 22B) is not directly depicted by the layout conceptual patterns, even though the vertical location of the individual frontside power rail and the width of the individual frontside power rail along the Y-direction are faithfully specified by the layout conceptual patterns. In FIG. 1, the full length of each of the frontside signal lines (122A-126A and 122B-126B) is not directly depicted by the layout conceptual patterns, even though the vertical location of the individual frontside signal line and the width of the individual frontside signal line along the Y-direction are faithfully specified by the layout conceptual patterns.

The layout diagram of FIG. 1 further includes the layout patterns for specifying backside signal lines 162 and 164. The backside signal line 164 is a one-dimensional signal line extending in the X-direction. The backside signal line 162 is a two-dimensional signal line having a first signal line segment 162H extending in the X-direction and a second signal line segment 162V extending in the Y-direction.

In FIG. 1, at least one of the gate-conductors (151A-159A and 151B-159B) intersects the p-type active-region structure 82p or 84p at a channel region of a PMOS transistor. At least one of the gate-conductors (151A-159A and 151B-159B) intersects the n-type active-region structure 82n or 84n at a channel region of an NMOS transistor. At least one of the terminal-conductors intersects the p-type active-region structure 82p or 84p at the source region of a PMOS transistor. At least one of the terminal-conductors intersects the n-type active-region structure 82n or 84n at the source region of an NMOS transistor. At least one of the terminal-conductors intersects the p-type active-region structure 82p or 84p at a drain region of a PMOS transistor. At least one of the terminal-conductors intersects the n-type active-region structure 82n or 84n at a drain region of an NMOS transistor.

In some embodiments, as various active-region structures in FIG. 1 are formed with fin structures, the PMOS transistors formed in p-type active-region structures (82p and 84p) and the NMOS transistors formed in n-type active-region structures (82n and 84n) are FinFETs. In some embodiments, as various active-region structures in FIG. 1 are formed with nano-sheet structures, the PMOS transistors formed in p-type active-region structures (82p and 84p) and the NMOS transistors formed in n-type active-region structures (82n and 84n) are nano-sheet transistors. In some embodiments, as various active-region structures in FIG. 1 are formed with nano-wire structures, the PMOS transistors formed in p-type active-region structures (82p and 84p) and the NMOS transistors formed in n-type active-region structures (82n and 84n) are nano-wire transistors.

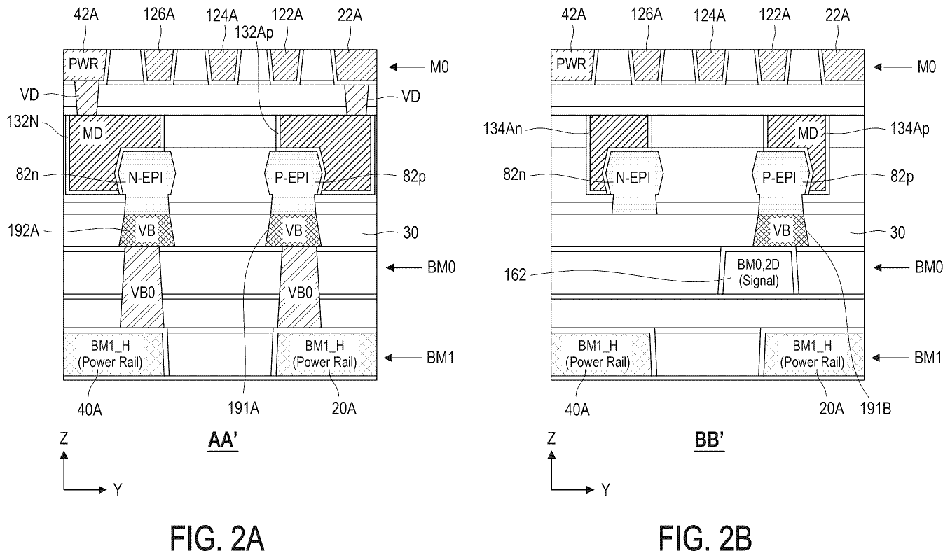

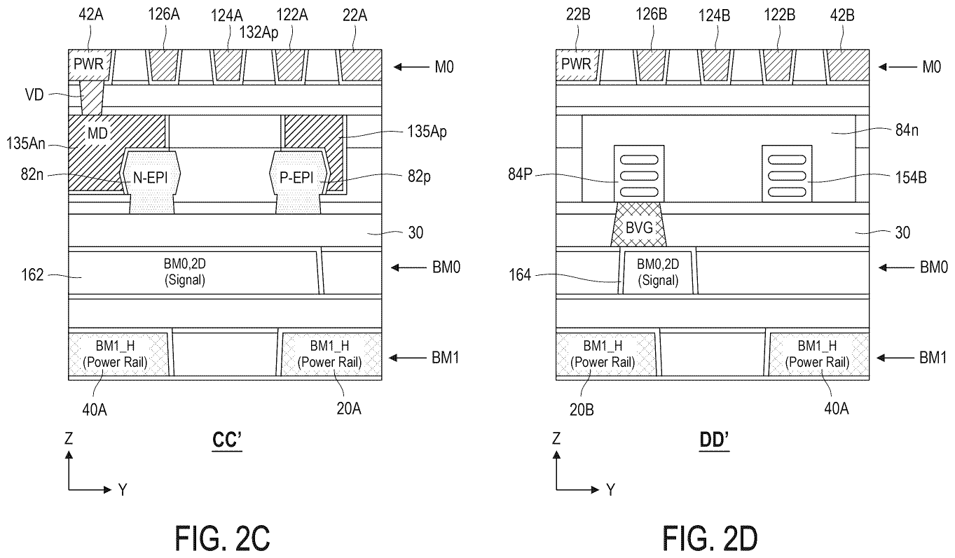

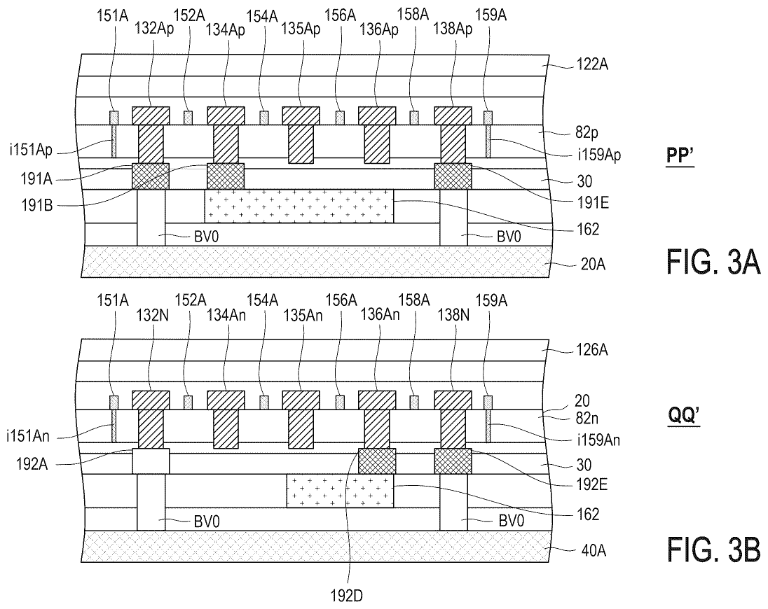

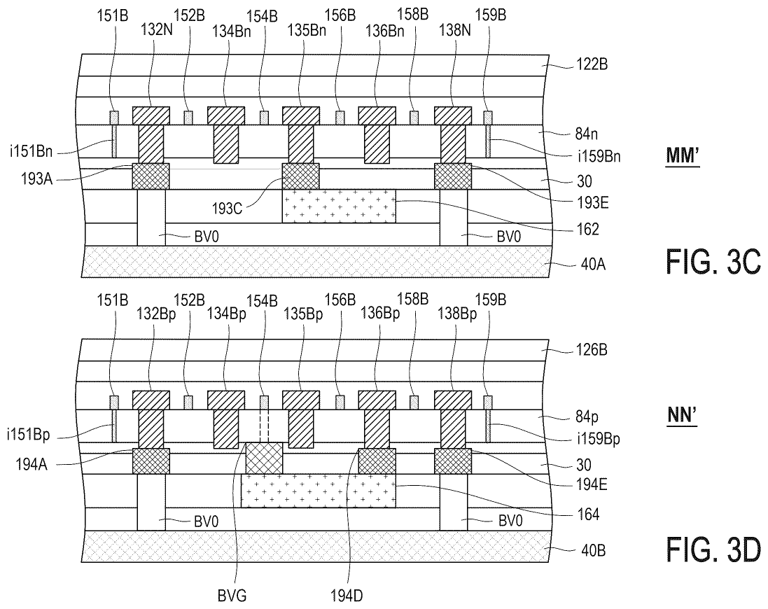

In the integrated circuit of FIG. 1, various active-region structures are formed on a substrate. The frontside power rails and frontside signal lines are formed at the frontside of the substrate, while the backside power rails and the backside signal lines are formed at the backside of the substrate, which are depicted in the cross-sectional views of the integrated circuit along various cutting planes as shown in FIGS. 2A-2D and FIGS. 3A-3D.

In FIGS. 2A-2D and FIGS. 3A-3D, the p-type active-region structures (82p and 84p) and the n-type active-region structures (82n and 84n) are formed on a substrate 30. Each of the terminal-conductors (132Ap-132Bp, 132N, 138Ap-138Bp, 138N,134Ap-136Ap, 134An-136An, 134B, 135Bn-136Bn, and 135Bp-136Bp) intersects one or more of the p-type active-region structures (82p and 84p) and the n-type active-region structures. Each of the gate-conductors (151A-159A and 151B-159B) also intersects one or more of the p-type active-region structures (82p and 84p) and the n-type active-region structures. The frontside power rails (22A, 42A, and 22B) and the frontside signal lines (122A-126A and 122B-126B) are formed in a frontside metal layer M0 which is above the terminal-conductors, the gate-conductors, and the active-region structures. The backside signal lines (162 and 164) are formed in a backside metal layer BM0 which is below the substrate 30. The backside power rails (20A, 40A, and 20B) are formed in a backside metal layer BM1 which is below the backside metal layer BM0.

FIG. 2A is a cross-sectional view of the integrated circuit in FIG. 1 along the cutting plane AA′, in accordance with some embodiments. In FIG. 2A, the terminal-conductor 132Ap is directly connected to the frontside power rail 22A through a frontside via-connector VD, and the terminal-conductor 132N is directly connected to the frontside power rail 42A through a frontside via-connector VD. A backside via-connector 191A is conductively connected to the terminal-conductor 132Ap which intersects the p-type active-region structures 82p at the source region of a PMOS transistor, and an extended via-connector VB0 is directly connected between the backside via-connector 191A and the backside power rail 20A. A backside via-connector 192A is conductively connected to the terminal-conductor 132N which intersects the n-type active-region structures 82n at the source region of an NMOS transistor, and an extended via-connector VB0 is directly connected between the backside via-connector 192A and the backside power rail 40A.

FIG. 2B is a cross-sectional view of the integrated circuit in FIG. 1 along the cutting plane BB′, in accordance with some embodiments. In FIG. 2B, the backside signal lines 162 is directly connected to a backside via-connector 191B which is further conductively connected to the terminal-conductor 134Ap intersecting the p-type active-region structures 82p.

FIG. 2C is a cross-sectional view of the integrated circuit in FIG. 1 along the cutting plane CC′, in accordance with some embodiments. In FIG. 2C, the terminal-conductor 135An is directly connected to the frontside power rail 42A through a frontside via-connector VD.

FIG. 2D is a cross-sectional view of the integrated circuit in FIG. 1 along the cutting plane DD′, in accordance with some embodiments. In FIG. 2D, the backside signal lines 164 is directly connected to a backside via-connector BVG which is further conductively connected to the gate-conductor 154B. The gate-conductor 154B intersects the p-type active-region structures 84p at the channel region of a PMOS transistor and intersects the n-type active-region structures 84n at the channel region of an NMOS transistor.

FIG. 3A is a cross-sectional view of the integrated circuit in FIG. 1 along the cutting plane PP′, in accordance with some embodiments. In FIG. 3A, a backside via-connector 191A is conductively connected to the terminal-conductor 132Ap which intersects the p-type active-region structures 82p at the source region of a PMOS transistor, and an extended via-connector VB0 is directly connected between the backside via-connector 191A and the backside power rail 20A. A backside via-connector 191E is conductively connected to the terminal-conductor 138Ap which intersects the p-type active-region structures 82p at the source region of a PMOS transistor, and an extended via-connector VB0 is directly connected between the backside via-connector 191E and the backside power rail 20A. The backside signal lines 162 is directly connected to a backside via-connector 191B which is further conductively connected to the terminal-conductor 134Ap intersecting the p-type active-region structures 82p.

FIG. 3B is a cross-sectional view of the integrated circuit in FIG. 1 along the cutting plane QQ′, in accordance with some embodiments. In FIG. 3B, a backside via-connector 192A is conductively connected to the terminal-conductor 132N which intersects the n-type active-region structures 82n at the source region of an NMOS transistor, and an extended via-connector VB0 is directly connected between the backside via-connector 192A and the backside power rail 40A. A backside via-connector 192E is conductively connected to the terminal-conductor 138N which intersects the n-type active-region structures 82n at the source region of an NMOS transistor, and an extended via-connector VB0 is directly connected between the backside via-connector 192E and the backside power rail 40A. The backside signal lines 162 is directly connected to a backside via-connector 192D which is further conductively connected to the terminal-conductor 136An intersecting the n-type active-region structures 82n.

FIG. 3C is a cross-sectional view of the integrated circuit in FIG. 1 along the cutting plane MM′, in accordance with some embodiments. In FIG. 3C, a backside via-connector 193A is conductively connected to the terminal-conductor 132N which intersects the n-type active-region structures 84n at the source region of an NMOS transistor, and an extended via-connector VB0 is directly connected between the backside via-connector 193A and the backside power rail 40A. A backside via-connector 193E is conductively connected to the terminal-conductor 138N which intersects the n-type active-region structures 84n at the source region of an NMOS transistor, and an extended via-connector VB0 is directly connected between the backside via-connector 193E and the backside power rail 40A. The backside signal lines 162 is directly connected to a backside via-connector 193C which is further conductively connected to the terminal-conductor 135Bn intersecting the n-type active-region structures 84n.

FIG. 3D is a cross-sectional view of the integrated circuit in FIG. 1 along the cutting plane NN′, in accordance with some embodiments. In FIG. 3D, a backside via-connector 194A is conductively connected to the terminal-conductor 132Bp which intersects the p-type active-region structures 84p at the source region of a PMOS transistor, and an extended via-connector VB0 is directly connected between the backside via-connector 194A and the backside power rail 20B. A backside via-connector 194E is conductively connected to the terminal-conductor 138Bp which intersects the p-type active-region structures 84p at the source region of a PMOS transistor, and an extended via-connector VB0 is directly connected between the backside via-connector 194E and the backside power rail 20B. The backside signal lines 164 is directly connected to a backside via-connector 194D which is further conductively connected to the terminal-conductor 136Bp intersecting the p-type active-region structures 84p. The backside signal lines 164 is also directly connected to a backside via-connector BVG which is further conductively connected to the gate-conductor 154B.

In FIGS. 3A-3B, the dummy gate-conductors 151A and 159A are correspondingly aligned with the vertical cell boundaries 101 and 109 as shown in FIG. 1. A boundary isolation region i151Ap in the p-type active-region structures 82p and a boundary isolation region i151An in the n-type active-region structures 82n are fabricated underneath the dummy gate-conductor 151A. A boundary isolation region i159Ap in the p-type active-region structures 82p and a boundary isolation region i159An in the n-type active-region structures 82n are fabricated underneath the dummy gate-conductor 159A. In FIGS. 3C-3D, the dummy gate-conductors 151B and 159B are correspondingly aligned with the vertical cell boundaries 101 and 109 as shown in FIG. 1. A boundary isolation region i151Bp in the p-type active-region structures 84p and a boundary isolation region i151Bn in the n-type active-region structures 84n are fabricated underneath the dummy gate-conductor 151B. A boundary isolation region i159Bp in the p-type active-region structures 84p and a boundary isolation region i159Bn in the n-type active-region structures 84n are fabricated underneath the dummy gate-conductor 159B.

The vertical cell boundary 101 of the circuit cell 100 in FIG. 1 is delineated with isolation regions i151Ap, i151An, i151Bn, and i151Bp. The vertical cell boundary 109 of the circuit cell 100 in FIG. 1 is delineated with isolation regions i159Ap, i159An, i159Bn, and i159Bp.

Each of the p-type active-region structures 82p and 84p include active regions (e.g., source regions, drain regions, and channel regions) of one or more PMOS transistors. Each of the n-type active-region structures 82n and 84n include active regions (e.g., source regions, drain regions, and channel regions) of one or more NMOS transistors. In FIG. 3A, the boundary isolation region i151Ap and the boundary isolation region i159Ap isolate the active regions of the PMOS transistors (in the p-type active-region structures 82p) of the circuit cell 100 from active regions of other PMOS transistors in the neighboring circuit cells. In FIG. 3B, the boundary isolation region i151An and the boundary isolation region i159An isolate the active regions of the NMOS transistors (in the n-type active-region structures 82n) of the circuit cell 100 from active regions of other NMOS transistors in the neighboring circuit cells. In FIG. 3C, the boundary isolation region i151Bn and the boundary isolation region i159Bn isolate the active regions of the NMOS transistors (in the n-type active-region structures 84n) of the circuit cell 100 from active regions of other NMOS transistors in the neighboring circuit cells. In FIG. 3D, the boundary isolation region i151Bp and the boundary isolation region i159Bp isolate the active regions of the PMOS transistors (in the p-type active-region structures 84p) of the circuit cell 100 from active regions of other PMOS transistors in the neighboring circuit cells.

In FIG. 1, the circuit cell 100 is a double height cell which is implemented with two parallelly positioned p-type active-region structures (i.e., 82p and 84p) and two parallelly positioned n-type active-region structures (i.e., 82n and 84n), and each of the vertical cell boundaries 101 and 109 passes through four isolation regions. In some other embodiments, a circuit cell 100 is a single height cell which is implemented with one p-type active-region structure and one n-type active-region structure, and consequently a vertical cell boundary of the single height cell passes through two isolation regions. That is, a vertical cell boundary of the single height cell passes through one isolation region in the p-type active-region structure and one isolation region in the n-type active-region structure.

Only one circuit cell 100 is shown in the integrated circuit of FIG. 1, and the circuit cell 100 is connected to the backside power rails 20A, 40A, and 20B. An integrated circuit often includes multiple circuit cells positioned in one or two cell rows, and the integrated circuit includes multiple cell rows.

FIG. 4 is layout diagram of an integrated circuit having arrays of backside power rails, in accordance with some embodiments. The integrated circuit includes backside power rails 20A-20D and backside power rails 40A-40C. Each of the backside power rails is formed in the second backside metal layer BM1 which is below the first metal layer BM0 that is at the backside of a substrate. Each of the backside power rails 20A-20D is configured to receive a first suppl voltage (such as the upper supply voltage VDD), and each of the backside power rails 40A-40C is configured to receive a second suppl voltage (such as the lower supply voltage VSS). The integrated circuit in FIG. 4 also includes backside signal lines formed in the first metal layer BM0 and includes various circuit cells. The backside signal lines formed in the first metal layer BM0 includes 462A-462C, 463A-463C, 464A, 465A-465B, 466A, and 467A-467C. The integrated circuit in FIG. 4 includes circuit cells 410A-410C, 420A, 420C, 430A-430C, 440A, 450A-450C, 460A, and 460C.

The circuit cells 410A, 410C, 420A, 420C, 430A-430C, 440A, 450A, 450C, 460A, and 460C are single height cells. The circuit cells 410B and 450B are double height cells. The backside power rail 20A is conductively connected to the circuit cells 420A-410C. The backside power rail 40A is conductively connected to the circuit cells 410A-410C, 420A, and 420C. The backside power rail 20B is conductively connected to the circuit cells 420A, 410B, 420C, and 430A-430C. The backside power rail 40B is conductively connected to the circuit cells 430A-430C and 440A. The backside power rail 20C is conductively connected to the circuit cells 440A and 450A-450C. The backside power rail 40C is conductively connected to the circuit cells 450A-450C, 460A, and 460C. The backside power rail 20D is conductively connected to the circuit cells 460A, 450B, and 460C.

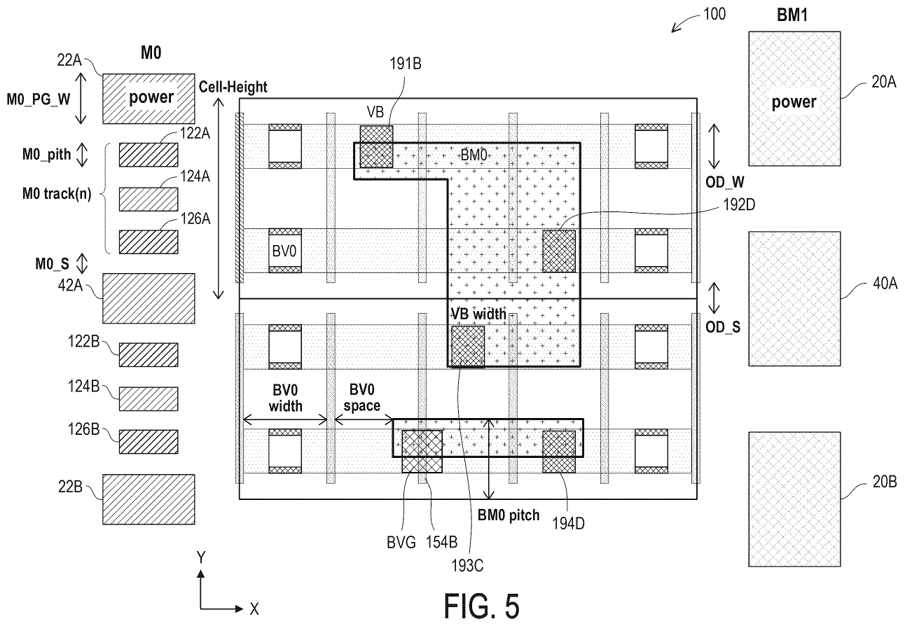

FIG. 5 is a layout diagram of an integrated circuit selectively labeled with geometric relationships, in accordance with some embodiments. The layout diagrams in FIG. 5 and FIG. 1, which share some common layout elements, are directed to the same layout design of an integrated circuit. The circuit cell 100 in FIG. 5 and FIG. 1 is a double height cell. The cell height of a double height cell is two times the cell height (i.e., “Cell-Height”) of a single height cell. The width of each of the backside power rails (20A, 40A, and 20B) is “BM1_W” and the space between two adjacent backside power rails is “BM1_S”. The single cell height “Cell-Height” satisfies the equation given by Cell-Height=BM1_W+BM1_S. The width of each of the frontside power rails (22A, 42A, and 22B) is “BM1_W” and the space between two adjacent frontside power rails is “M0_PG_W”, the pitch distance between two frontside signal lines (e.g. 122A-126A) is “M0_pitch”, and the space between a frontside signal line and a frontside power rail is “M0_S”. The single cell height “Cell-Height” satisfies the equation given by Cell-Height=M0_PG_W+M0_S+n*M0_pitch, wherein the integer “n” is the number of frontside signal lines between two adjacent frontside power rails. In the example of FIG. 5 and FIG. 1, the number of frontside signal lines between two adjacent frontside power rails is three.

In the layout diagrams in FIG. 5 and FIG. 1, the width of each of the active-region structure (e.g., the p-type active-region structure 82p or the n-type active-region structure 82n) is “OD_W”, the space the space between two adjacent n-type active-region structures (e.g., 82n and 84n) is “OD_S”. The width “BM1_W” of the backside power rail 40A satisfies the equation given by BM1_W>=OD_S+2*(0.5*OD_W). In some embodiments, the width of the backside via-connector (e.g., 191B, 183C, 192D, or 194D) is equal to the width “OD_W” of an active-region structure, and the width of a backside via-connector BVG (such as, the backside via-connector BVG conductively connected to the gate-conductor 154B) is also equal to the width “OD_W” of an active-region structure.

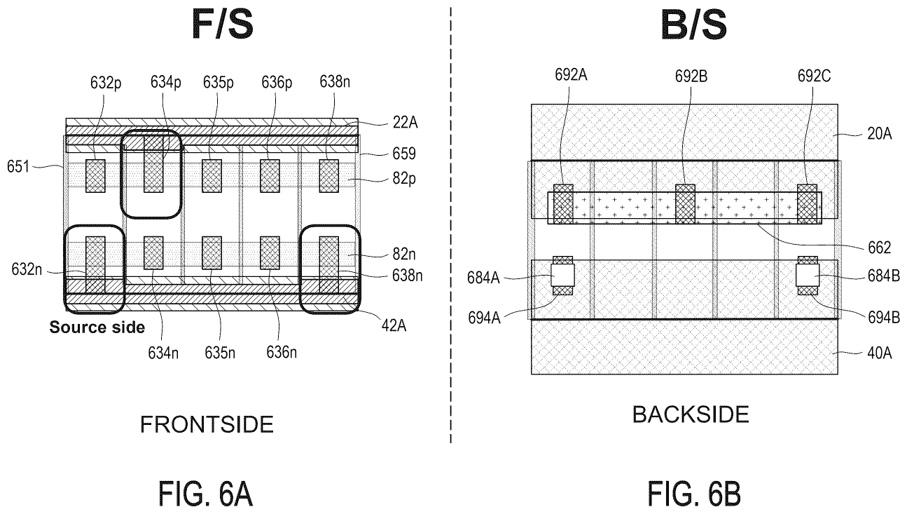

FIGS. 6A-6B are layout diagrams of a circuit cell 600 connected to frontside power rails and backside power rails, in accordance with some embodiments. The frontside layout diagram of FIG. 6A includes the layout patterns for specifying a p-type active-region structure 82p and an n-type active-region structure 82n extending in the X-direction, terminal-conductors 632p-638p and 632-638n extending in the Y-direction, and frontside power rails 22A and 42A extending in the X-direction. The frontside layout diagram of FIG. 6A also includes the layout patterns for specifying dummy gate-conductors 651 and 659. The dummy gate-conductor 651 is located at a first vertical cell boundary of the circuit cell 600 and the dummy gate-conductor 659 is located at a second vertical cell boundary of the circuit cell 600. Each of the active-region structures has isolation regions (under the dummy gate-conductors 651 and 659) which isolate the active regions of the transistors in the circuit cell 600 from active regions of other transistors in the neighboring circuit cells.

The backside layout diagram of FIG. 6B includes the layout patterns for specifying backside power rails 20A and 40A extending in the X-direction, a backside signal line 662 extending in the X-direction, backside via-connectors (694A and 694B), and extended via-connectors (684A and 684B). The backside signal line 662 is formed in a first backside metal layer which is below a substrate. The backside power rails 20A and 40A are formed in a second backside metal layer which is below the first backside metal layer.

In FIG. 6A, the frontside power rail 22A is configured to be maintained at an upper supply voltage VDD, and the frontside power rail 42A is configured to be maintained at a lower supply voltage VSS. The terminal-conductor 634p intersects the p-type active-region structure 82p at a source region of a PMOS transistor and is connected to the frontside power rail 22A. Each of the terminal-conductors 632n and 638n intersects the n-type active-region structure 82n at a source region of an NMOS transistor and is connected to the frontside power rail 42A. Each of the terminal-conductors 632p, 635p, and 638p in FIG. 6A intersects the p-type active-region structure 82p at either a source region or a drain region of a PMOS transistor.

In FIG. 6B, the backside power rail 20A is configured to be maintained at an upper supply voltage VDD, and the backside power rail 40A is configured to be maintained at a lower supply voltage VSS. Each of the terminal-conductors 632p, 635p, and 638p is connected to the backside signal line 662 correspondingly through one of the backside via-connectors 692A, 692B, and 692C. The terminal-conductor 632n is conductively connected to the backside via-connector 694A which passes through the substrate. The backside via-connector 694A is further connected to the backside power rail 40A through the extended via-connector 684A. The terminal-conductor 638n is conductively connected to the backside via-connector 694B which passes through the substrate. The backside via-connector 694B is further connected to the backside power rail 40A through the extended via-connector 684B.

In circuit cell 600, each of the terminal-conductors 632n and 638n is conductively connected to both the frontside power rail 42A and the backside power rail 40A. Each conductive connection from the frontside power rail 42A to the backside power rail 40A through a terminal-conductor (such as, through the terminal-conductor 632n or through the terminal-conductor 638n) forms a conduction path between the frontside power rail 42A and the backside power rail 40A. Increasing the number of conduction paths between the frontside power rail 42A to the backside power rail 40A decreases IR drops between the frontside power rail 42A to the backside power rail 40A, which improves the performance of the integrated circuit having the circuit cell 600.

Similarly, a conductive connection from the frontside power rail 22A to the backside power rail 20A through a terminal-conductor would form a conduction path between the frontside power rail 22A and the backside power rail 20A. Increasing the number of conduction paths between the frontside power rail 22A to the backside power rail 20A decreases IR drops between the frontside power rail 22A to the backside power rail 20A. In circuit cell 600, however, a conductive connection from the frontside power rail 22A to the backside power rail 20A is not formed through the terminal-conductor 634p. In the specific implementation of the circuit cell 600 as shown in FIGS. 6A-6B, the terminal-conductor 634p is not connected to the backside power rail 20A through one or more backside via-connectors underneath the terminal-conductor 634p, because of some design rule restrictions due to the positioning of the backside signal line 662.

In some embodiments, the layout design of a circuit cell (such as the circuit cell 600) is subjected to optimization process to increase the number of conduction paths from the frontside power rail 42A to the backside power rail 40A or to increase the number of conduction paths from the frontside power rail 22A to the backside power rail 20A. In some embodiments, increasing the number of conduction paths between a frontside power rail and a corresponding backside power rail improves the performance of an integrated circuit which has circuit cells therein subjected to the optimization process.

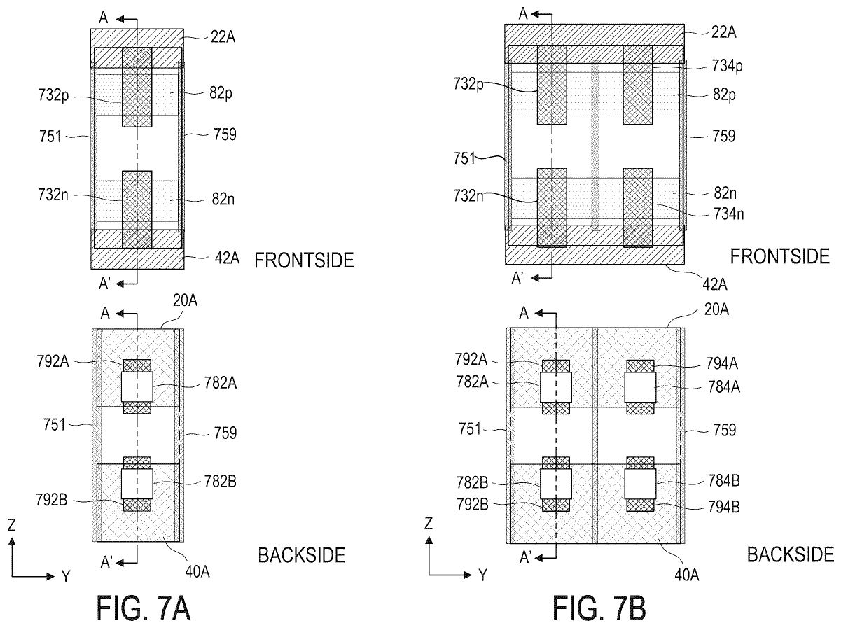

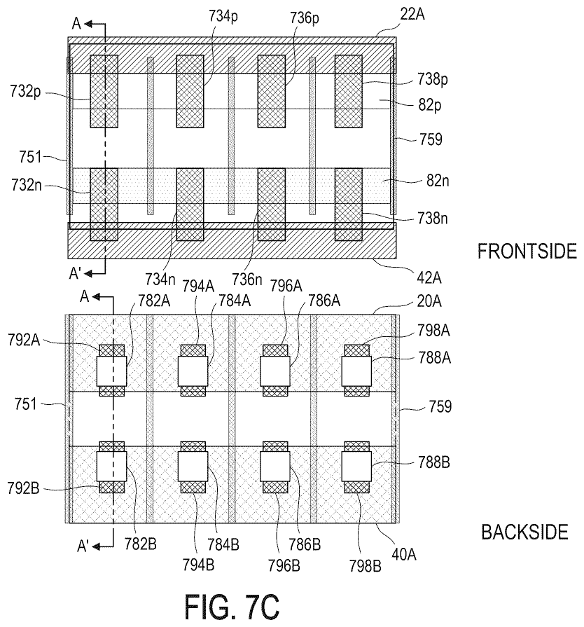

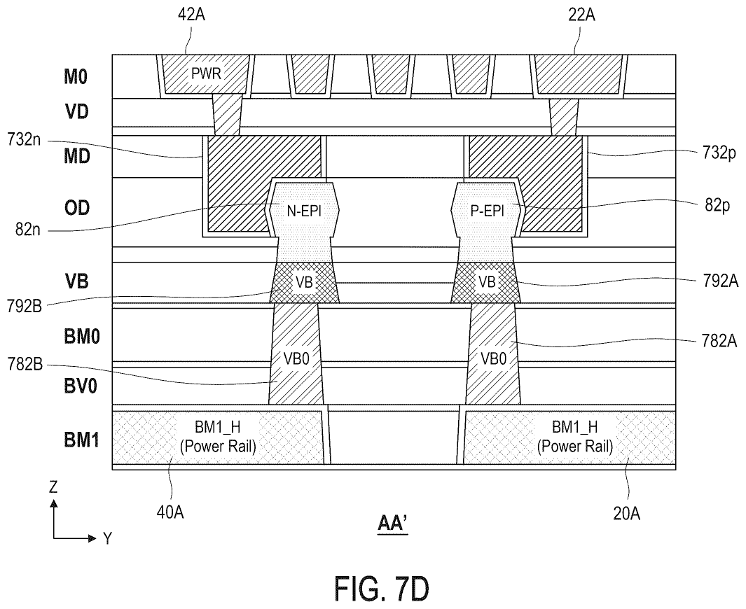

In a layout diagram of an integrated circuit, multiple functional circuit cells are often positioned in one or two cell rows, and the integrated circuit includes multiple cell rows. Dummy cells are positioned in some of the layout areas between the multiple functional circuit cells along one or two cell rows. A functional circuit includes at least one logic gate or at least at least one analog circuit which is configured to have a second signal at an output node responsive to a first signal at an input node. In some embodiments, the dummy cell is implemented as a filler cell or as a power pickup cell. A dummy cell (such as a power pickup cell) either contains no transistor or has each transistor in the dummy cell implemented as a dummy transistor. A dummy transistor receives no time-varying signal at the gate or transmits no signal at the drain or the source to other devices as a time-varying signal. A dummy cell contains no functioning logic gate. A functioning logic gate is a logic gate that generates a time-varying logic output signal in responsive to a time-varying logic input signal received at an input. Example implementations of power pickup cells are depicted in the layout diagrams in FIGS. 7A-7C.

FIGS. 7A-7C are layout diagrams of power pickup cells, in accordance with some embodiments. Each of the frontside layout diagrams in FIGS. 7A-7C includes the layout patterns for specifying a p-type active-region structure 82p and an n-type active-region structure 82n extending in the X-direction, frontside power rails 22A and 44A extending in the X-direction, dummy gate-conductors 751 and 759 extending in the Y-direction, and various terminal-conductors extending in the Y-direction.

The dummy gate-conductor 751 is located at a first vertical cell boundary and the dummy gate-conductor 759 is located at a second vertical cell boundary. Each of the active-region structures has isolation regions (under the dummy gate-conductors 751 and 759) which isolate the active regions of the transistors in a power pickup cell from active regions in the neighboring circuit cells. The power pickup cell in FIG. 7A has a cell width of one CPP, the power pickup cell in FIG. 7B has a cell width of two CPPs, and the power pickup cell in FIG. 7C has a cell width of four CPPs.

In the frontside layout diagram in FIG. 7A, the terminal-conductor 732p intersects the p-type active-region structure 82p, and the terminal-conductor 732n intersects the n-type active-region structure 82n. In the frontside layout diagram in FIG. 7B, each of the terminal-conductors 732p-734p intersects the p-type active-region structure 82p, and each of the terminal-conductors 732n-734n intersects the n-type active-region structure 82n. In the frontside layout diagram in FIG. 7C, each of the terminal-conductors 732p-738p intersects the p-type active-region structure 82p, and each of the terminal-conductors 732n-738n intersects the n-type active-region structure 82n.

Each of the backside layout diagrams in FIGS. 7A-7C includes the layout patterns for specifying backside power rails 20A and 40A extending in the X-direction, various backside via-connectors, and various extended via-connectors at the backside of the substrate. The backside power rails 20A and 40A are formed in the second backside metal layer which is below the first backside metal layer at the backside of the substrate. Each of the backside via-connectors passes through the substrate. Each of the extended via-connectors directly connects one of the backside power rails 20A and 40A to one of the backside via-connectors.

In FIGS. 7A-7B, the frontside power rail 22A is configured to be maintained at a first supply voltage (e.g., VDD), and the frontside power rail 42A is configured to be maintained a second supply voltage (e.g., VSS). The backside power rail 20A is configured to be maintained at a first supply voltage (e.g., VDD), and the backside power rail 40A is configured to be maintained at a second supply voltage (e.g., VSS).

In FIGS. 7A-7C, the frontside power rail 22A is conductively connected to the terminal-conductor 732p, a backside via-connector 792A is also conductively connected to the terminal-conductor 732p. An extended via-connector 782A is directly connected between the backside via-connector 792A and the backside power rail 20A. The frontside power rail 42A is conductively connected to the terminal-conductor 732n, a backside via-connector 792B is also conductively connected to the terminal-conductor 732n. An extended via-connector 782B is directly connected between the backside via-connector 792B and the backside power rail 40A.

Furthermore, in FIGS. 7B-7C, the frontside power rail 22A is conductively connected to the terminal-conductor 734p, a backside via-connector 794A is also conductively connected to the terminal-conductor 734p. An extended via-connector 784A is directly connected between the backside via-connector 794A and the backside power rail 20A. The frontside power rail 42A is conductively connected to the terminal-conductor 734n, a backside via-connector 794B is also conductively connected to the terminal-conductor 734n. An extended via-connector 784B is directly connected between the backside via-connector 794B and the backside power rail 40A.

In addition, in FIG. 7C, the frontside power rail 22A is conductively connected to the terminal-conductor 736p, a backside via-connector 796A is also conductively connected to the terminal-conductor 736p. An extended via-connector 786A is directly connected between the backside via-connector 796A and the backside power rail 20A. The frontside power rail 42A is conductively connected to the terminal-conductor 736n, a backside via-connector 796B is also conductively connected to the terminal-conductor 736n. An extended via-connector 786B is directly connected between the backside via-connector 796B and the backside power rail 40A. The frontside power rail 22A is conductively connected to the terminal-conductor 738p, a backside via-connector 798A is also conductively connected to the terminal-conductor 738p. An extended via-connector 788A is directly connected between the backside via-connector 798A and the backside power rail 20A. The frontside power rail 42A is conductively connected to the terminal-conductor 738n, a backside via-connector 798B is also conductively connected to the terminal-conductor 738n. An extended via-connector 788B is directly connected between the backside via-connector 798B and the backside power rail 40A.

FIG. 7D is a cross-sectional view of the power pickup cells in FIGS. 7A-7C along the cutting plane AA′, in accordance with some embodiments. In FIG. 7D, a conduction path passing through the terminal-conductors 732p is formed between the frontside power rail 22A and the backside power rail 20A. Specifically, the frontside power rail 22A is connected to the terminal-conductors 732p through a frontside via-connector VD, and the terminal-conductors 732p is in conductive contact with an active region P-EPI of the p-type active-region structure 82p. The backside via-connector 792A is connected to the active region P-EPI of the p-type active-region structure 82p, and the extended via-connector 782A is directly connected between the backside via-connector 792A and the backside power rail 20A. Similarly, in FIG. 7D, a conduction path passing through the terminal-conductors 732n is formed between the frontside power rail 42A and the backside power rail 40A. Specifically, the frontside power rail 42A is connected to the terminal-conductors 732n through a frontside via-connector VD, and the terminal-conductors 732n is in conductive contact with an active region N-EPI of the n-type active-region structure 82n. The backside via-connector 792B is connected to the active region N-EPI of the n-type active-region structure 82n, and the extended via-connector 782B is directly connected between the backside via-connector 792B and the backside power rail 40A.

In each of the power pickup cells of FIGS. 7A-7C, one or more conduction paths is formed between the frontside power rail 22A and the backside power rail 20A, and one or more conduction paths is formed between the frontside power rail 42A and the backside power rail 40A. Increasing the number of power pickup cells in an integrated circuit decreases IR drops between frontside power rails and backside power rail, which improves the performance of the integrated circuit.

In the power pickup cell of FIG. 7A, one conduction path passing through the terminal-conductor 732p is formed between the frontside power rail 22A and the backside power rail 20A, and one conduction path passing through the terminal-conductor 732n is formed between the frontside power rail 42A and the backside power rail 40A. In the power pickup cell of FIG. 7B, two conduction paths (which correspondingly pass through the terminal-conductors 732p-734p) are formed between the frontside power rail 22A and the backside power rail 20A, and two conduction paths (which correspondingly pass through the terminal-conductors 732n-734n) are formed between the frontside power rail 42A and the backside power rail 40A. In the power pickup cell of FIG. 7C, four conduction path (which correspondingly pass through the terminal-conductors 732p-738p) are formed between the frontside power rail 22A and the backside power rail 20A, and four conduction paths (which correspondingly pass through the terminal-conductors 732p-738p) are formed between the frontside power rail 42A and the backside power rail 40A.

In FIGS. 7A-7C and FIG. 7D, at least one conduction path between a frontside power rail and a backside power rail is implemented with an extended via-connector directly connected between a backside via-connector and a backside power rail. In some alternative embodiments, a conduction path between a frontside power rail and a backside power rail is implemented with a backside conductor in the first backside metal layer. One backside via-connector is conductively connected between the frontside power rail and the backside conductor, and another backside via-connector is conductively connected between the backside conductor and the backside power rail.

In FIGS. 7A-7C and FIG. 7D, each of the power pickup cells has both at least one conduction path between the frontside power rail 22A and the backside power rail 20A and at least one conduction path between the frontside power rail 42A and the backside power rail 40A. In some alternative embodiments, a power pickup cell has at least one conduction path between the frontside power rail 22A and the backside power rail 20A but is implemented with any conduction path between the frontside power rail 42A and the backside power rail 40A. In some alternative embodiments, a power pickup cell has at least one conduction path between the frontside power rail 42A and the backside power rail 40A but is implemented with any conduction path between the frontside power rail 22A and the backside power rail 20A.

In some layout designs of integrated circuits, single-stage cells are implemented as due-side power cells (“DSP” cells) having backside power lines in the first backside metal layer (e.g., BM0) below the substrate, while multi-stage cells are implemented with backside signal lines in the first backside metal layer (e.g., BM0) and implemented with backside power rails in the second backside metal layer (e.g., BM1) below the first backside metal layer (e.g., BM0). Examples of single-stage cells include a buffer cell, an inverter cell, a NAND cell, a NOR cell, an AND cell, or an OR cell. Examples of multi-stage cells include an AND-OR-invert (AOI), a flip flop, or multiple single-stage gates connected in series. In one example, a multi-stage cell is formed with three inverters connected in series to perform the inverter function. In some embodiments, a multi-stage cell includes a first logic gate and a second logic gate serially connected between an input of the first logic gate and an output of the second logic gate such that an input of the second logic gate is configured to receive a logic signal from an output of the first logic gate.

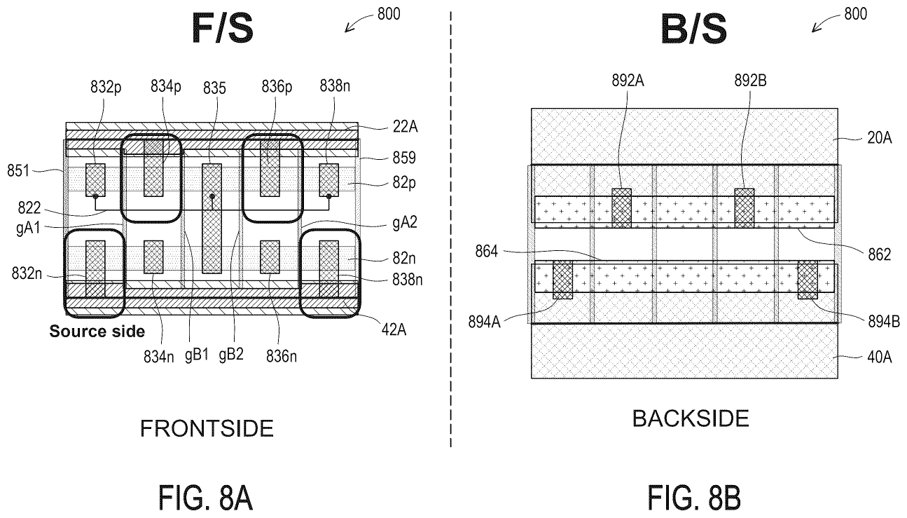

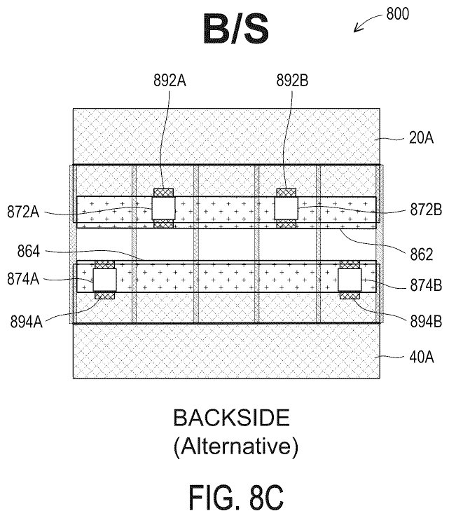

FIGS. 8A-8B are layout diagrams of a single-stage cell 800 in the form of a DSP cell, in accordance with some embodiments. The DSP cell has backside power lines 862 and 864 in the backside metal layer BM0 below the substrate. The single-stage cell 800 in FIGS. 8A-8B is an implementation of a NAND gate.

In the frontside layout diagram of FIG. 8A, the terminal-conductors 832p-834p and 836p-838p intersect the p-type active-region structure 82p, the terminal-conductors 832n-834n and 836n-838n intersect the n-type active-region structure 82n, the terminal-conductor 835 intersects both the p-type active-region structure 82p and the n-type active-region structure 82n. The gate-conductor gA1 intersects the p-type active-region structure 82p and the n-type active-region structure 82n correspondingly at channel regions of a PMOS transistor TA1p and an NMOS transistor TA1n. The gate-conductor gB1 intersects the p-type active-region structure 82p and the n-type active-region structure 82n correspondingly at channel regions of a PMOS transistor TB1p and an NMOS transistor TB1n. The gate-conductor gB2 intersects the p-type active-region structure 82p and the n-type active-region structure 82n correspondingly at channel regions of a PMOS transistor TB2p and an NMOS transistor TB2n. The gate-conductor gA2 intersects the p-type active-region structure 82p and the n-type active-region structure 82n correspondingly at channel regions of a PMOS transistor TA2p and an NMOS transistor TA2n.

The gate-conductors gA1 and gA2 are connected together and configured to receive a first input signal “A”. The gate-conductors gB1 and gB2 are connected together and configured to receive a second input signal “B”. The terminal-conductor 835 is configured to generate an output signal “Z”.

The frontside power rails 22A and 42A extending in the X-direction are formed in a frontside metal layer M0 which is above the terminal-conductors and the gate-conductors. A frontside signal line 822 extending in the X-direction is also formed in the frontside metal layer M0, which is conceptually represented in FIG. 8A by the conducting line connected to the terminal-conductors 832p, 835, and 838p. Each of the terminal-conductors 832p, 835, and 838p is connected to the frontside signal line 822 through a corresponding frontside via-connector VD, whereby the drain terminals of the PMOS transistors TA1p, TBp1, TB2p, and TA2p are all connecting together.

The frontside power rail 22A is configured to be maintained at an upper supply voltage VDD, and the frontside power rail 42A is configured to be maintained at a lower supply voltage VSS. Each of the terminal-conductors 834p and 836p is connected to the frontside power rails 22A, whereby connecting the source terminals of the PMOS transistors TA1p, TBp1, TB2p, and TA2p to the upper supply voltage VDD. Each of the terminal-conductors 832n and 838n is connected to the frontside power rails 42A, whereby connecting the source terminals of the NMOS transistors TA1n and TA2n to the lower supply voltage VSS.

In the backside layout diagram of FIG. 8B, the backside power lines 862 and 864 extending in the X-direction are formed in the backside metal layer BM0 below the substrate. The backside power rails 20A and 40A extending in the X-direction are formed in a backside metal layer BM1 which is below the backside metal layer BM0. The backside power rail 20A is configured to be maintained at an upper supply voltage VDD, and the backside power rail 40A is configured to be maintained at a lower supply voltage VSS. Each of the terminal-conductors 634p and 636p is conductively connected to the backside power line 862 correspondingly through one of the backside via-connectors 892A and 892B. Each of the terminal-conductors 632n and 638n is conductively connected to the backside power line 864 correspondingly through one of the backside via-connectors 894A and 894B. In FIG. 8B, each of the backside power lines 862 and 864 does not extend across the vertical cell boundary of the single-stage cell. Each of the backside power lines 862 and 864 has a length (along the X-direction) which is smaller than the cell width of the single-stage cell 800, where the cell width is measured along the X-direction between the two vertical cell boundaries.

In an alternative implementation, as shown in the backside layout diagram of FIG. 8C, the single-stage cell 800 further includes backside via-connectors 872A and 872B and backside via-connectors 874A and 874B. Each of the backside via-connectors 872A and 872B is directly connected between the backside power line 862 and the backside power rails 20A. Each of the backside via-connectors 874A and 874B is directly connected between the backside power line 864 and the backside power rails 40A. With the backside via-connectors 872A and 872B and the backside power line 862, the number of conduction paths between the frontside power rail 22A to the backside power rail 20A is increased, thereby decreasing IR drops between the frontside power rail 22A to the backside power rail 20A. With the backside via-connectors 874A and 874B and the backside power line 864, the number of conduction paths between the frontside power rail 42A to the backside power rail 40A is increased, thereby decreasing IR drops between the frontside power rail 42A to the backside power rail 40A.

In FIGS. 8A-8B, with the single-stage cell 800 being implemented as a DSP cell, the backside power lines 862 and 864 in the backside metal layer BM0 has the beneficial effects of lowering the ID drops associated with the power rails. Despite that the single-stage cell 800 does not include a backside signal line (such as the one similar to the backside signal line 662 of FIG. 6), the loss of the benefits of placing an opposite phase signal in a backside signal line is outweighed by the gaining of the beneficial effects of lowering the ID drops associated with the power rails.

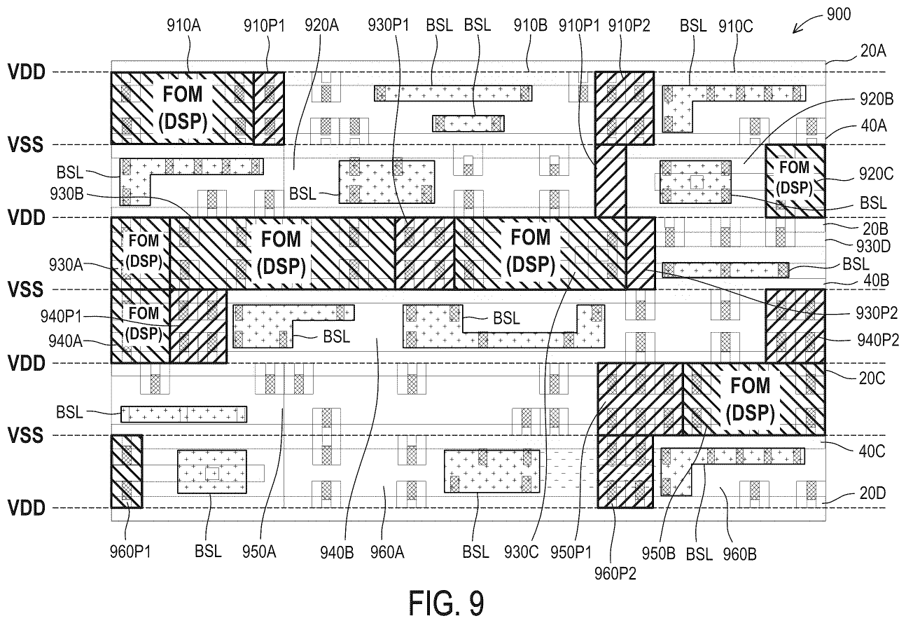

FIG. 9 is a layout diagram of an integrated circuit 900 having single-stage cells and multi-stage cells, in accordance with some embodiments. The integrated circuit 900 includes backside power rails 20A-20D and backside power rails 40A-40C. Each of the backside power rails is formed in the second backside metal layer BM1 which is below the first metal layer BM0 that is at the backside of a substrate. Each of the backside power rails 20A-20D is configured to receive a first suppl voltage (such as the upper supply voltage VDD), and each of the backside power rails 40A-40C is configured to receive a second supply voltage (such as the lower supply voltage VSS).

The integrated circuit in FIG. 9 includes circuit cells 910A-910C, 920A-920C, 930A-930D, 940A-940B, 950A-950B, and 960A-960B. Some of the circuit cells are single-stage cells, while some of the circuit cells are multi-stage cells. The single-stage cells include circuit cells 910A, 920C, 930A-930C, 940A, and 950B. Each of the single-stage cells has backside power lines in the first backside metal layer below the substrate. The multi-stage cells include circuit cells 910B-910C, 920A-920B, 930D, 940B, 950A, and 960A-960B. Each of the multi-stage cells has one or more backside signal lines BSL. Each backside signal line BSL is in the first backside metal layer below the substrate. The integrated circuit in FIG. 9 also includes power pick up cells 910P1-910P2, 920P1, 930P1-930P2, 940P1-940P2, 950P1, and 960P1-960P2. Some example implementations of the power pickup cells are shown in the layout diagrams of FIGS. 7A-7C.

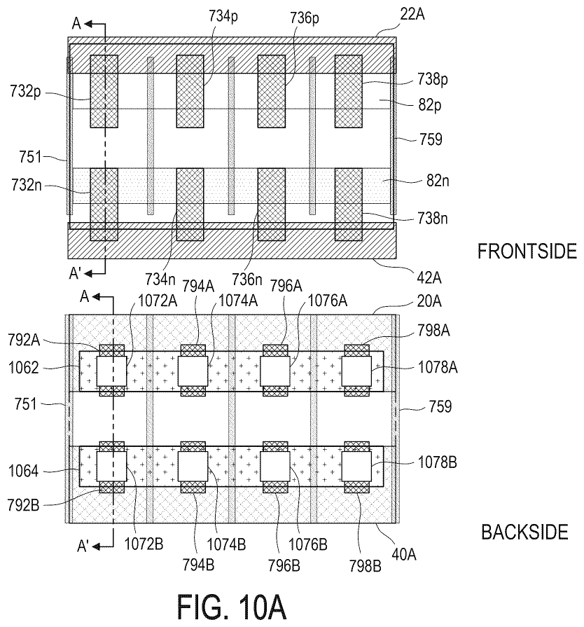

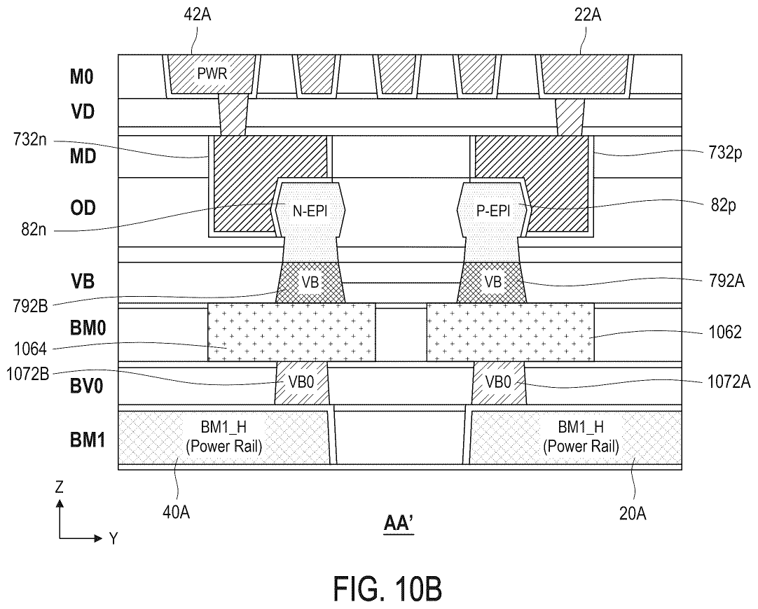

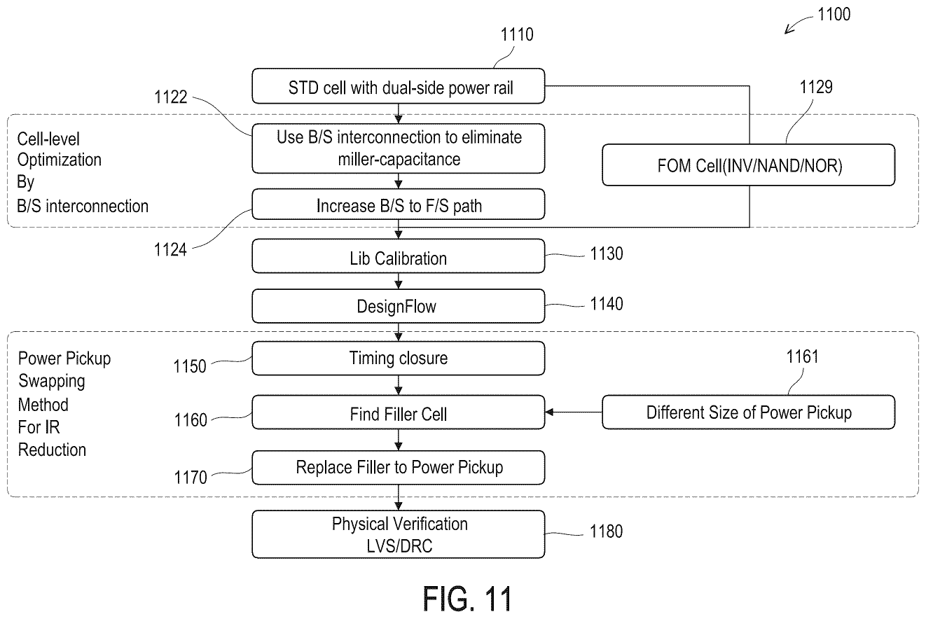

FIG. 10A is another example implementation of the power pickup cell, in accordance with some embodiments. The power pickup cell in FIG. 10A is modified from the power pickup cell in FIG. 7C. With the modification, the conductive connection from each of the backside via-connectors 792A, 794A, 796A, and 798A to the backside power rail 20A is changed, and the conductive connection from each of the backside via-connectors 792B, 794B, 796B, and 798B to the backside power rail 40A is also changed.

In FIG. 10A, backside conductors 1062 and 1064 are formed in the first backside metal layer BM0 below the substate, while the backside power rails 20A and 40A are formed in the second backside metal layer BM1 below the first backside metal layer BM0. Each of the backside via-connectors 792A, 794A, 796A, and 798A is connected to the backside conductor 1062, and the backside conductor 1062 is further connected to the backside power rail 20A correspondingly through one of the backside via-connectors 1072A, 1074A, 1076A, and 1078A (which pass through the interlayer dielectric between the first backside metal layer BM0 and the second backside metal layer BM1). Each of the backside via-connectors 792B, 794B, 796B, and 798B is connected to the backside conductor 1064, and the backside conductor 1064 is further connected to the backside power rail 40A correspondingly through one of the backside via-connectors 1072B, 1074B, 1076B, or 1078B (which pass through the interlayer dielectric between the first backside metal layer BM0 and the second backside metal layer BM1).

FIG. 10B is a cross-sectional view of the power pickup cell in FIG. 10A along the cutting plane AA′, in accordance with some embodiments. As the power pickup cell in FIG. 10A is modified from the power pickup cell in FIG. 7, the conduction path from the frontside power rail 22A to the backside power rail 20A through the terminal-conductor 732p is modified, and the conduction path from the frontside power rail 42A to the backside power rail 40A through the terminal-conductor 732n is also modified.

In the conduction path from the frontside power rail 22A to the backside power rail 20A through the terminal-conductor 732p, as shown in FIG. 10B, the backside via-connector 792A is connected to the backside conductor 1062 which is further connected to the backside power rail 20A through the backside via-connectors 1072A. In the conduction path from the frontside power rail 42A to the backside power rail 40A through the terminal-conductor 732n, as shown in FIG. 10B, the backside via-connector 792B is connected to the backside conductor 1064 which is further connected to the backside power rail 40A through the backside via-connectors 1072B.

FIG. 11 is a flowchart of method 1100 of generating an integrated circuit having backside power rails, in accordance with some embodiments. The sequence in which the operations of method 1100 are depicted in FIG. 11 is for illustration only; the operations of method 1100 are capable of being executed in sequences that differ from that depicted in FIG. 11. It is understood that additional operations may be performed before, during, and/or after the method 1100 depicted in FIG. 11, and that some other processes may only be briefly described herein.

In operation 1110 of method 1100, standard cells are designed as DSP cells. Each DSP cell has backside power lines in the first backside metal layer (e.g., BM0) below the substrate and has backside power rails (e.g., 20A, 40A) in the second backside metal layer (e.g., BM1) below the first backside metal layer (e.g., BM0). The DSP cells with dual-side power rails are either designed during the operation or fetched from existing standard cell libraries. An example layout design of a DSP cell is shown in the layout diagrams of FIGS. 8A-8B. The DSP cell in FIGS. 8A-8B has the backside power lines 862 and 864 in the first backside metal layer BM0.

In operations which follow operation 1110, cell-level optimization is performed for the standard cells generated and analyzed in operation 1110. If a standard cell is a single-stage cell (such as, a FOM cell implemented as an inverter, a NAND gate, or a NOR gate), then, in operation 1129, the single-stage cell is deposited into the library for calibration.

If a standard cell is a multi-stage cell, then, in operation 1122, the multi-stage cell is redesigned with backside signal lines to eliminate various stray capacitance (such as, the miller-capacitance, or the stray capacitance due to cross coupling between two or more conductors). As one example, to eliminate the stray capacitance due to the capacitive coupling between two parallel conducting lines which carry signals of opposite phases, one of the two parallel conducting line is substituted with a backside signal line in the first backside metal layer (e.g., BM0) below the substrate, and the signal originally carried by the substituted conducting line is rerouted to the newly implemented backside signal line. In the example layout of FIG. 9, each of the multi-stage cells in the integrated circuit of FIG. 9 has one or more backside signal lines BSL. In the example as shown in FIGS. 6A-6B, the backside signal line 662 is implemented to carry a signal, thereby reducing capacitive couplings between some conducting lines carrying signals of opposite phases. After operation 1122, operation 1124 is carried out for the redesigned multi-stage cell.

In operation 1124, one or more conduction paths from frontside power rails to backside power rails are added to the redesigned multi-stage cell obtained in operation 1122, if the spaces in the layout design are available for adding more backside via-connectors and/or extended via-connectors. In the example as shown in FIGS. 6A-6B, two conduction paths from the frontside power rail 42A to the backside power rail 40A are formed. One conduction path passes through the terminal-conductor 632n, the backside via-connector 694A, and the extended via-connector 684A. Another conduction path passes through the terminal-conductor 638n, the backside via-connector 694B, and the extended via-connector 684B. After operation 1124, library calibration is performed in operation 1130, design flow is carried out in operation 1140, and timing closure is carried out in operation 1150.

Next, in operation 1160 and operation 1170, the filler cells in the layout design obtained in operation 1140 are swapped with power pickup cells, thereby reducing the IR drops associated with the frontside power rails and the backside power rails. Specifically, in operation 1160, the layout design obtained in operation 1140 is searched for filler cells, and for each detected filler cell, the cell width of the detected filler cell is determined. Based on the cell width of the detected filler cell, in operation 1161, a matched power pickup cell is used as a replacement. Then, in operation 1170, each detected filler cell is replaced with the matched power pickup cell. The matched power pickup cell has a cell width smaller than or equal to that of the detected filler cell to be substituted. In some embodiments, each detected filler cell is replaced with a matched power pickup cell of same cell width. For example, in some embodiments, each detected filler cell of one-CPP wide is replaced with the power pickup cell in FIG. 7A, each detected filler cell of two-CPP wide is replaced with the power pickup cell in FIG. 7B, and each detected filler cell of four-CPP wide is replaced with the power pickup cell in FIG. 7C. After operation 1170, in operation 1180, physical verification on the layout design is performed. Examples of physical verification include design rule checks (DRC), layout versus schematic verifications (LVS), antenna checks, and electrical rule checks (ERC).

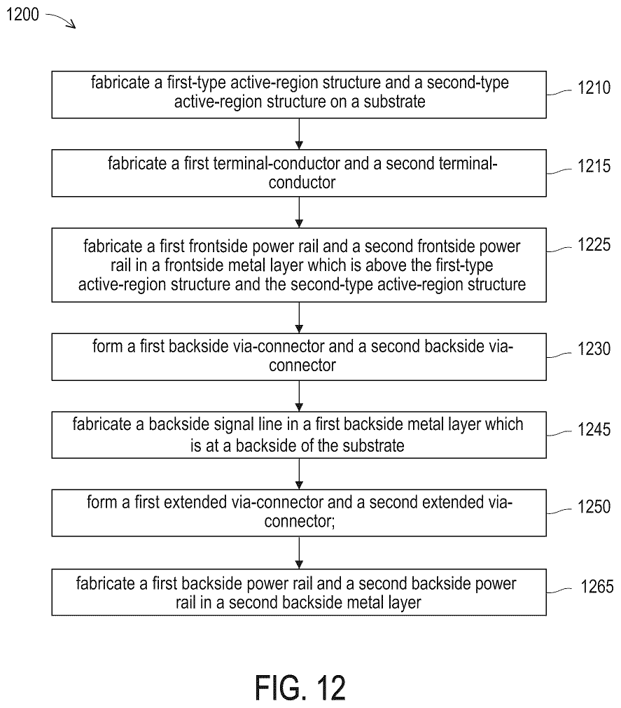

FIG. 12 is a flowchart of method 1200 of manufacturing an integrated circuit, in accordance with some embodiments. The sequence in which the operations of method 1200 are depicted in FIG. 12 is for illustration only; the operations of method 1200 are capable of being executed in sequences that differ from that depicted in FIG. 12. It is understood that additional operations may be performed before, during, and/or after the method 1200 depicted in FIG. 12, and that some other processes may only be briefly described herein.

In operation 1210 of method 1200, a first-type active-region structure and a second-type active-region structure are fabricated on a substrate. In the example as shown in FIG. 2A and FIGS. 3A-3B, the p-type active-region structure 82p and the n-type active-region structures 82n are fabricated on the substrate 30.

In operation 1215 of method 1200, a first terminal-conductor and a second terminal-conductor are fabricated. In the example as shown in FIG. 2A and FIGS. 3A-3B, the terminal-conductor 132Ap intersecting the p-type active-region structure 82p and the terminal-conductor 132N intersecting the n-type active-region structure 82n are fabricated.

In operation 1225 of method 1200, a first frontside power rail and a second frontside power rail are fabricated in a frontside metal layer which above the first-type active-region structure and the second-type active-region structure. In the example as shown in FIG. 2A and FIGS. 3A-3B, the frontside power rail 22A and the frontside power rail 42A are fabricated in the first frontside metal layer M0 overlying the interlayer dielectric which covers the p-type active-region structure 82p and the n-type active-region structures 82n. The terminal-conductor 132Ap is connected to the frontside power rail 22A through a corresponding frontside via-connector VD and the terminal-conductor 132N is connected to the frontside power rail 42A through a corresponding frontside via-connector VD.

In operation 1230 of method 1200, a first backside via-connector and a second backside via-connector are formed. In the example as shown in FIG. 2A and FIGS. 3A-3B, the backside via-connectors 191A and 192A passing through the substrate 30 are formed. The backside via-connectors 191A is connected to the active region P-EPI of the p-type active-region structure 82p, while the active region P-EPI is in conductive contact with the terminal-conductor 132Ap. The backside via-connectors 192A is connected to the active region N-EPI of the n-type active-region structure 82n, while the active region N-EPI is in conductive contact with the terminal-conductor 132N.

In operation 1245 of method 1200, a backside signal line is fabricated a first backside metal layer which at the backside of the substrate. In the example as shown in FIG. 2A and FIGS. 3A-3B, The backside signal line 162 is fabricated in the first backside metal layer BM0 at the backside of the substrate 30.

In operation 1250 of method 1200, a first extended via-connector and a second extended via-connector are formed. In the example as shown in FIG. 2A and FIGS. 3A-3B, the extended via-connector BV0 connected to the backside via-connectors 191A and the extended via-connector BV0 connected to the backside via-connectors 192A are formed to pass through both the first backside metal layer BM0 and the interlayer dielectric in contact with the first backside metal layer BM0.

In operation 1265 of method 1200, a first backside power rail and a second backside power rail are fabricated in a second backside metal layer. In the example as shown in FIG. 2A and FIGS. 3A-3B, the backside power rails 20A and 40A are fabricated in the second backside metal layer BM1 deposited on the interlayer dielectric that is in contact with the first backside metal layer BM0. The backside power rails 20A is directly connected to the backside via-connector 191A with the extended via-connector BV0 that is in contact with the backside via-connector 191A. The backside power rails 40A is directly connected to the backside via-connector 192A with the extended via-connector BV0 that is in contact with the backside via-connector 192A.

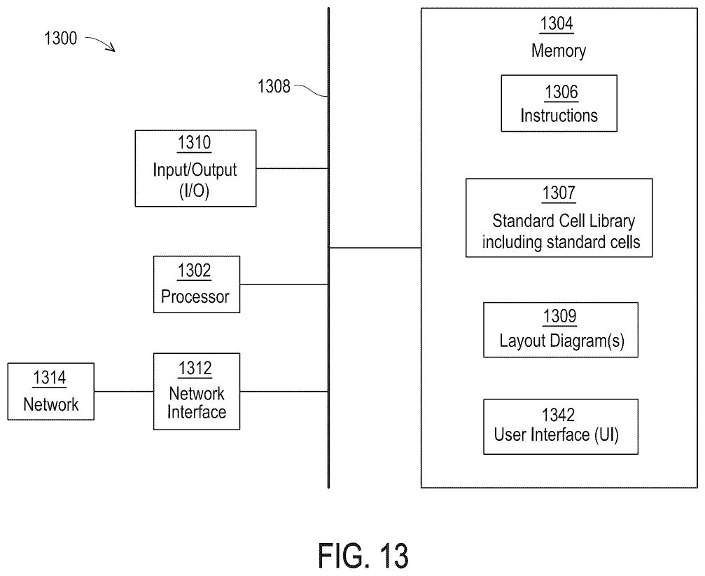

FIG. 13 is a block diagram of an electronic design automation (EDA) system 1300 in accordance with some embodiments.

In some embodiments, EDA system 1300 includes an automatic placement and routing (APR) system. Methods described herein of designing layout diagrams represent wire routing arrangements, in accordance with one or more embodiments, are implementable, for example, using EDA system 1300, in accordance with some embodiments.

In some embodiments, EDA system 1300 is a general purpose computing device including a hardware processor 1302 and a non-transitory, computer-readable storage medium 1304. Storage medium 1304, amongst other things, is encoded with, i.e., stores, computer program code 1306, i.e., a set of executable instructions. Execution of instructions 1306 by hardware processor 1302 represents (at least in part) an EDA tool which implements a portion or all of the methods described herein in accordance with one or more embodiments (hereinafter, the noted processes and/or methods).

Processor 1302 is electrically coupled to computer-readable storage medium 1304 via a bus 1308. Processor 1302 is also electrically coupled to an I/O interface 1310 by bus 1308. A network interface 1312 is also electrically connected to processor 1302 via bus 1308. Network interface 1312 is connected to a network 1314, so that processor 1302 and computer-readable storage medium 1304 are capable of connecting to external elements via network 1314. Processor 1302 is configured to execute computer program code 1306 encoded in computer-readable storage medium 1304 in order to cause system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, computer-readable storage medium 1304 is an electronic, magnetic, optical, electromagnetic, infrared, and/or a semiconductor system (or apparatus or device). For example, computer-readable storage medium 1304 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1304 includes a compact disk-read only memory (CD-ROM), a compact disk-read/write (CD-R/W), and/or a digital video disc (DVD).

In one or more embodiments, storage medium 1304 stores computer program code 1306 configured to cause system 1300 (where such execution represents (at least in part) the EDA tool) to be usable for performing a portion or all of the noted processes and/or methods. In one or more embodiments, storage medium 1304 also stores information which facilitates performing a portion or all of the noted processes and/or methods. In one or more embodiments, storage medium 1304 stores library 1307 of standard cells including such standard cells as disclosed herein. In one or more embodiments, storage medium 1304 stores one or more layout diagrams 1309 corresponding to one or more layouts disclosed herein.

EDA system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

EDA system 1300 also includes network interface 1312 coupled to processor 1302. Network interface 1312 allows system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1300.

System 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via bus 1308. EDA system 1300 is configured to receive information related to a user interface (UI) through I/O interface 1310. The information is stored in computer-readable medium 1304 as UI 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

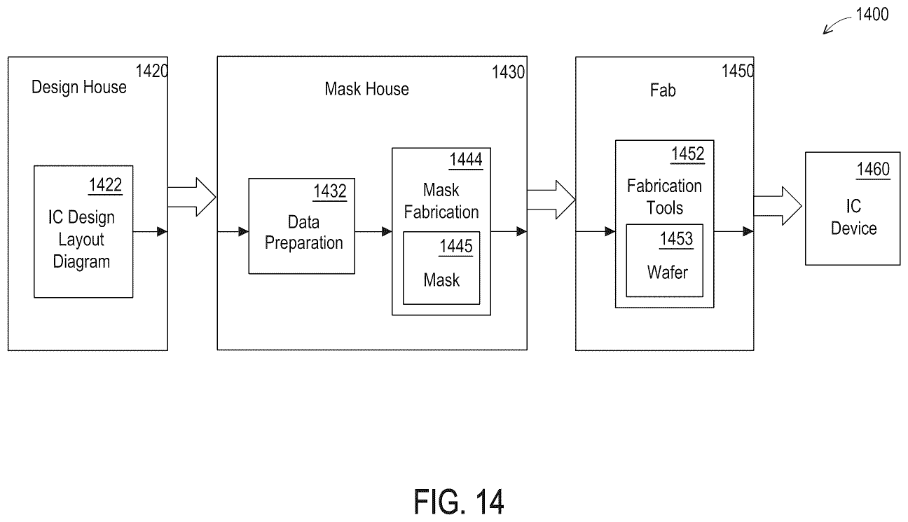

FIG. 14 is a block diagram of an integrated circuit (IC) manufacturing system 1400, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1420, a mask house 1430, and an IC manufacturer/fabricator (fab) 1450, that interact with one another in the design, development, and manufacturing cycles and/or services related to manufacturing an IC device 1460. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout diagram 1422. IC design layout diagram 1422 includes various geometrical patterns designed for an IC device 1460. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1430 includes data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (RDF). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout diagram 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for photolithographic implementation effects during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purposes of clarity. In some embodiments, data preparation 1432 includes additional features such as a logic operation (LOP) to modify the IC design layout diagram 1422 according to manufacturing rules. Additionally, the processes applied to IC design layout diagram 1422 during data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC Fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

An aspect of the present disclosure relates to a method of manufacturing an integrated circuit. The method includes fabricating a first-type active-region structure and a second-type active-region structure each extending in a first direction on a substrate. The method also includes fabricating a first terminal-conductor and a second terminal-conductor, where the first terminal-conductor intersects the first-type active-region structure at a source region of a first-type transistor, and where the second terminal-conductor intersects the second-type active-region structure at a source region of a second-type transistor; fabricating a first frontside power rail and a second frontside power rail in a frontside metal layer, where each of the first frontside power rail and the second frontside power rail extends in the first direction, and where the frontside metal layer is above the first-type active-region structure and the second-type active-region structure. The method also includes forming a first backside via-connector conductively connected to the source region of the first-type transistor and forming a second backside via-connector conductively connected to the source region of the second-type transistor; fabricating a backside signal line in a first backside metal layer at a backside of the substrate; forming a first extended via-connector and a second extended via-connector; and fabricating a first backside power rail and a second backside power rail in a second backside metal layer, where the first backside power rail extending in the first direction is directly connected to the first backside via-connector with the first extended via-connector and the second backside power rail extending in the first direction is directly connected to the second backside via-connector with the second extended via-connector, and where the first backside metal layer is between the second backside metal layer and the substrate.

Another aspect of the present disclosure also relates to a method of manufacturing an integrated circuit. The method includes fabricating a first-type active-region structure and a second-type active-region structure each extending in a first direction on a substrate. The method also includes fabricating a first terminal-conductor intersecting the first-type active-region structure at a source region of a first-type transistor; fabricating a first frontside power rail extending in the first direction in a frontside metal layer which is above the first-type active-region structure and the second-type active-region structure; fabricating a first backside via-connector conductively connected to the source region of the first-type transistor; fabricating a backside signal line in a first backside metal layer below the substrate; fabricating a first extended via-connector directly connected to the first backside via-connector; and fabricating a first backside power rail extending in the first direction which is directly connected to the first extended via-connector, where the first backside power rail is in a second backside metal layer below the first backside metal layer.

Another aspect of the present disclosure still relates to a method of manufacturing an integrated circuit. The method also includes fabricating a first-type active-region structure and a second-type active-region structure each extending in a first direction on a substrate; fabricating a first frontside power rail extending in the first direction in a frontside metal layer which is above the first-type active-region structure and the second-type active-region structure; fabricating a backside signal line in a first backside metal layer below the substrate; fabricating a first backside power rail and a second backside power rail, each extending in the first direction, in a second backside metal layer below the first backside metal layer; forming a multi-stage cell having a first logic gate and a second logic gate serially connected between an input of the first logic gate and an output of the second logic gate such that an input of the second logic gate is configured to receive a logic signal from an output of the first logic gate. The method also includes fabricating a first-type transistor in the multi-stage cell having a source region in the first-type active-region structure conductively connected to the first backside power rail through one or more via-connectors. The method also includes fabricating a second-type transistor in the multi-stage cell having a source region in the second-type active-region structure conductively connected to the second backside power rail through one or more via-connectors.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A method of manufacturing an integrated circuit, the method comprising:
fabricating a first-type active-region structure and a second-type active-region structure each extending in a first direction on a substrate;
fabricating a first terminal-conductor and a second terminal-conductor, wherein the first terminal-conductor intersects the first-type active-region structure at a source region of a first-type transistor, and wherein the second terminal-conductor intersects the second-type active-region structure at a source region of a second-type transistor;
fabricating a first frontside power rail and a second frontside power rail in a frontside metal layer, wherein each of the first frontside power rail and the second frontside power rail extends in the first direction, and wherein the frontside metal layer is above the first-type active-region structure and the second-type active-region structure;
forming a first backside via-connector conductively connected to the source region of the first-type transistor and forming a second backside via-connector conductively connected to the source region of the second-type transistor;
fabricating a backside signal line in a first backside metal layer at a backside of the substrate;
forming a first extended via-connector and a second extended via-connector; and
fabricating a first backside power rail and a second backside power rail in a second backside metal layer, wherein the first backside power rail extending in the first direction is directly connected to the first backside via-connector with the first extended via-connector and the second backside power rail extending in the first direction is directly connected to the second backside via-connector with the second extended via-connector, and wherein the first backside metal layer is between the second backside metal layer and the substrate.

2. The method of claim 1, further comprising:
fabricating the backside signal line in the first backside metal layer before fabricating a first backside power rail and a second backside power rail.

3. The method of claim 2, wherein fabricating the backside signal line comprises:
fabricating the backside signal line as a two-dimensional signal line which has a first signal line segment extending in the first direction and a second signal line segment extending in a second direction which is perpendicular to the first direction.

4. A method of manufacturing an integrated circuit, the method comprising:
fabricating a first-type active-region structure and a second-type active-region structure each extending in a first direction on a substrate;
fabricating a first terminal-conductor intersecting the first-type active-region structure at a source region of a first-type transistor;
fabricating a first frontside power rail extending in the first direction in a frontside metal layer which is above the first-type active-region structure and the second-type active-region structure;
fabricating a first backside via-connector conductively connected to the source region of the first-type transistor;
fabricating a backside signal line in a first backside metal layer below the substrate;
fabricating a first extended via-connector directly connected to the first backside via-connector; and
fabricating a first backside power rail extending in the first direction which is directly connected to the first extended via-connector, wherein the first backside power rail is in a second backside metal layer below the first backside metal layer.

5. The method of claim 4, further comprising:
fabricating a first frontside via-connector directly connected to the first terminal-conductor; and
connecting the first frontside power rail directly to the first frontside via-connector.

6. The method of claim 4, further comprising:
fabricating a second terminal-conductor intersecting the second-type active-region structure at a source region of a second-type transistor;
fabricating a second frontside power rail extending in the first direction the frontside metal layer;
fabricating a second backside via-connector conductively connected to the source region of the second-type transistor;
fabricating a second extended via-connector directly connected to the second backside via-connector; and
fabricating a second backside power rail extending in the first direction which is directly connected to the second extended via-connector, wherein the second backside power rail is in the second backside metal layer.

7. The method of claim 6, further comprising:
fabricating a second frontside via-connector directly connected to the second terminal-conductor; and
connecting the second frontside power rail directly to the second frontside via-connector.

8. The method of claim 4, further comprising:
fabricating a third terminal-conductor intersecting the first-type active-region structure or the second-type active-region structure at a drain region of a transistor;
fabricating a third backside via-connector directly connected to the third terminal-conductor; and
connecting the backside signal line directly to the third backside via-connector.

9. The method of claim 4, further comprising:
fabricating a gate-conductor intersecting the first-type active-region structure or the second-type active-region structure at a channel region of a transistor;
fabricating a third backside via-connector directly connected to the gate-conductor; and
connecting the backside signal line directly to the third backside via-connector.

10. The method of claim 4, wherein the backside signal line is a two-dimensional signal line having a first signal line segment extending in the first direction and a second signal line segment extending in a second direction which is perpendicular to the first direction.

11. A method of manufacturing an integrated circuit, the method comprising:
fabricating a first-type active-region structure and a second-type active-region structure each extending in a first direction on a substrate;
fabricating a first frontside power rail extending in the first direction in a frontside metal layer which is above the first-type active-region structure and the second-type active-region structure;
fabricating a backside signal line in a first backside metal layer below the substrate;
fabricating a first backside power rail and a second backside power rail, each extending in the first direction, in a second backside metal layer below the first backside metal layer;
forming a multi-stage cell having a first logic gate and a second logic gate serially connected between an input of the first logic gate and an output of the second logic gate such that an input of the second logic gate is configured to receive a logic signal from an output of the first logic gate;
fabricating a first-type transistor in the multi-stage cell having a source region in the first-type active-region structure conductively connected to the first backside power rail through one or more via-connectors; and
fabricating a second-type transistor in the multi-stage cell having a source region in the second-type active-region structure conductively connected to the second backside power rail through one or more via-connectors.

12. The method of claim 11, further comprising:
fabricating a first backside via-connector conductively connected to the source region of the first-type transistor; and
fabricating a first extended via-connector directly connected between the first backside via-connector and the first backside power rail.

13. The method of claim 12, further comprising:
fabricating a second backside via-connector conductively connected to the source region of the second-type transistor; and
fabricating a second extended via-connector directly connected between the second backside via-connector and the second backside power rail.

14. The method of claim 11, wherein the multi-stage cell has a first vertical cell boundary and a second vertical cell boundary extending in a second direction perpendicular to the first direction, and wherein each of the first vertical cell boundary and the second vertical cell boundary passes through a first boundary isolation region in the first-type active-region structure and a second boundary isolation region in the second-type active-region structure.

15. The method of claim 11, further comprising:
forming a power pickup cell, wherein the power pickup cell either contains no transistor or has each transistor therein implemented as a dummy transistor.

16. The method of claim 15, wherein forming the power pickup cell comprises:
fabricating a first terminal-conductor intersecting the first-type active-region structure; and
fabricating a first frontside via-connector directly connected between the first terminal-conductor and the first frontside power rail.

17. The method of claim 16, wherein the power pickup cell further comprises:
fabricating a first backside via-connector conductively connected to the first terminal-conductor; and
fabricating a first extended via-connector directly connected between the first backside via-connector and the first backside power rail.

18. The method of claim 15, wherein the power pickup cell further comprises:
fabricating a first backside conductor formed in the first backside metal layer, wherein a first backside via-connector is conductively connected to the first backside power rail through the first backside conductor.

19. The method of claim 15, wherein the power pickup cell further comprises:
fabricating a second terminal-conductor intersecting the second-type active-region structure;
fabricating a second frontside via-connector directly connected between the second terminal-conductor and a second frontside power rail; and
fabricating a second backside via-connector conductively connected between the second terminal-conductor and the second backside power rail.

20. The method of claim 15, wherein the power pickup cell has a first vertical cell boundary and a second vertical cell boundary extending in a second direction perpendicular to the first direction, and wherein each of the first vertical cell boundary and the second vertical cell boundary passes through a first boundary isolation region in the first-type active-region structure and a second boundary isolation region in the second-type active-region structure.
